(19) United States
(12) Patent Application Publication
(10) Pub. No.: US 2015/0325461 A1
(43) Pub. Date: Nov. 12, 2015

(54) Method of Packaging Semiconductor Devices and Apparatus for Performing the Same

(71) Applicant: Dongbu Hitek Co., Ltd., Seoul (KR)

(72) Inventors: Jun Il Kim, Gyeonggi-do (KR); Sung Jin Kim, Gyeonggi-do (KR); Hag Mo Kim, Gyeonggi-do (KR)

(21) Appl. No.: 14/496,374

(22) Filed: Sep. 25, 2014

(30) Foreign Application Priority Data
May 9, 2014 (KR) 10-2014-0055232

(51) Int. Cl. H01L 21/67; H01L 21/56; H01L 23/373

(52) U.S. Cl. CPC H01L 21/67126; H01L 23/3737; H01L 21/67259; H01L 21/561; H01L 21/563

(57) ABSTRACT

Provided is a method of packaging semiconductor devices mounted on a flexible substrate having a longitudinally extending tape shape and including packaging areas arranged along the extending direction thereof. An empty area, on which a semiconductor device is not mounted, is detected from among the packaging areas. When the empty area is detected, a heat dissipation paint composition is applied on the semiconductor devices mounted on the remaining packaging areas except for the empty area to form first heat dissipation layers. When the empty is not detected, the heat dissipation paint composition is applied on the semiconductor devices mounted on the packaging areas to form second heat dissipation layers. Here, the first dissipation layers are formed by a potting process, and the second heat dissipation layers are formed by a screen printing process.

### CROSS-REFERENCE TO RELATED APPLICATION

This application claims priority to Korean Patent Application No. 10-2014-0055232 filed on May 9, 2014 and all the benefits accruing therefrom under 35 U.S.C. §119, the contents of which are herein incorporated by reference in their entirety.

### BACKGROUND

The present disclosure relates to a method of packaging semiconductor devices and an apparatus for performing the same, and more particularly, to a method of packaging semiconductor devices mounted on a flexible substrate, such as a chip on film (COF) tape, a tape carrier package (TCP) tape or the like, and an apparatus for performing the same.

Generally, a display apparatus such as a liquid crystal display (LCD) may include a liquid crystal panel and a backlight unit disposed on a rear of the liquid crystal panel. Semiconductor devices such as driver integrated circuits (IC) may be employed to drive the liquid crystal panel. These semiconductor devices may be connected to the liquid crystal panel using packaging techniques such as COF, TCP, chip on glass (COG), and the like.

High resolution display devices may require an increased driving load to be provided by the semiconductor device. In the particular case of COF-type semiconductor packages, this increased driving load may cause increased heat generation, leading to problems associated with the need for increased heat dissipation.

To address the need for increased heat dissipation, some prior art methods have been developed that involve the addition of a heat sink using an adhesion member. For example, Korean Laid-Open Patent Publication No. 10-2009-0110206 discloses a COF type semiconductor package including a flexible substrate, a semiconductor device mounted on the top surface of the flexible substrate and a heat sink mounted on the bottom surface of the flexible substrate by using an adhesion member.

However, heat sinks mounted on the bottom surface of flexible substrate may be inefficient due to the relatively low thermal conductivity of the flexible substrate. In addition, such heat sinks typically have a plate shape made by using a metal such as aluminum, which may reduce the flexibility of the COF type semiconductor package. Furthermore, over time and through normal use, the heat sink may become separated from the flexible substrate.

### SUMMARY

The present disclosure provides a packaging method that is capable of sufficiently improving the heat dissipation efficiency of the semiconductor devices and an apparatus for performing the packaging method.

In accordance with an exemplary embodiment, a method of packaging semiconductor devices mounted on a flexible substrate having a longitudinally extending tape and including packaging areas arranged along an extending direction thereof may include detecting an empty area on which a semiconductor device is not mounted from among the packaging areas. The method may also include, in response to detecting the empty area, applying a heat dissipation paint composition on the semiconductor devices mounted on the remaining packaging areas except for the empty area to form first heat dissipation layers. The method may also include, in response to not detecting the empty area, applying the heat dissipation paint composition on the semiconductor devices mounted on the packaging areas to form second heat dissipation layers. The first heat dissipation layers are formed by a potting process, and the second heat dissipation layers is formed by a screen printing process.

In some exemplary embodiments, the flexible substrate may be transferred through a first packaging module for performing the potting process and a second packaging module for performing the screen printing process.

In some exemplary embodiments, when the empty area from among the packaging areas located in a processing region of the first packaging module is detected, the potting process may be performed on the remaining packaging areas located in the processing region of the first packaging module simultaneously, except for the empty area. In some exemplary embodiments, when the empty area is not detected from among the packaging areas located in a processing region of the first packaging module, the packaging areas located in the processing region of the first packaging module may be transferred into the second packaging module.

In some exemplary embodiments, the screen printing process on the packaging areas located in a processing region of the second packaging module may be performed at the same time.

In some exemplary embodiments, the method may further include curing the first or second heat dissipation layers.

In some exemplary embodiments, the flexible substrate may be transferred through a curing module, and the first or second heat dissipation layers may be cured by heaters disposed in the curing module.

In some exemplary embodiments, the method may further include forming underfill layers filling spaces defined between the flexible substrate and the semiconductor devices.

In some exemplary embodiments, the forming of the underfill layers may include transferring the flexible substrate through an underfill module, and forming the underfill layers between the packaging areas of the flexible substrate and the semiconductor devices located in a processing region of the underfill module. An underfill process may be omitted on the empty area.

In some exemplary embodiments, the method may further include curing the underfill layers.

In some exemplary embodiments, the heat dissipation paint composition may include approximately 1 wt % to approximately 5 wt % of an epichlorohydrin bisphenol A resin, approximately 1 wt % to approximately 5 wt % of a modified epoxy resin, approximately 1 wt % to approximately 10 wt % of a curing agent, approximately 1 wt % to approximately 5 wt % of a curing accelerator and the remaining amount of a heat dissipation filler.

In some exemplary embodiments, the modified epoxy resin may be a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin or a silicon modified epoxy resin.

In some exemplary embodiments, the curing agent may be a novolac type phenolic resin.

In some exemplary embodiments, the curing accelerator may be an imidazole-based curing accelerator or an amine-based curing accelerator.

In some exemplary embodiments, the heat dissipation filler may include aluminum oxide having a particle size of approximately 0.01 pin to approximately 50 μm.

Further exemplary embodiments may include, a method of packaging semiconductor devices mounted on a flexible substrate having a longitudinally extending tape shape, including packaging areas arranged along an extending direction thereof, and on which a plurality of packaging groups constituted by the predetermined number of packaging areas are defined. The method may include transferring the flexible substrate through a first packaging module in which a potting process is performed to form first heat dissipation layers on the semiconductor devices and a second packaging module in which a screen printing process is performed to form second heat dissipation layers on the semiconductor devices. The method may also include detecting an empty area on which a semiconductor device is not mounted from among the packaging areas. The method includes, in response to detecting the empty area, applying a heat dissipation paint composition on the semiconductor devices mounted on the remaining packaging areas of the packaging group except for the empty area, to form the first heat dissipation layers. The method also includes, in response to not detecting the empty area, applying the heat dissipation paint composition on the semiconductor devices mounted on a packaging areas of the packaging group to form the second heat dissipation layers.

Additional exemplary embodiments include an apparatus for packaging semiconductor devices mounted on a flexible substrate having a longitudinally extending tape shape and including packaging areas arranged along an extending direction thereof. The apparatus may include an unwinder module configured to supply the flexible substrate, a rewinder module configured to recover the flexible substrate, and a first packaging module disposed between the unwinder module and the rewinder module to apply a heat dissipation paint composition on the semiconductor devices by using a potting process. The first packaging module is configured to form first heat dissipation layers which package the semiconductor devices. The apparatus also includes a second packaging module disposed between the first packaging module and the rewinder module to apply the heat dissipation paint composition on the semiconductor devices using a screen printing process. The second packaging module is configured to form second heat dissipation layers which package the semiconductor devices. The apparatus further includes a control unit configured to detect an empty area on which a semiconductor device is not mounted from among the packaging areas, to control operations of the first packaging module to form the first heat dissipation layers on the semiconductor devices mounted on the remaining packaging areas except for the empty area when the empty is detected, and to control operations of the second packaging module to form the second heat dissipation layers on the semiconductor devices when the empty area is not detected.

In some exemplary embodiments, the apparatus may further include a curing module configured to cure the first or second heat dissipation layers.

In some exemplary embodiments, the apparatus may further include an underfill module configured to form underfill layers between the flexible substrate and the semiconductor devices.

In some exemplary embodiments, the apparatus may further include a pre-curing module configured to cure the underfill layers.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWINGS

Exemplary embodiments can be understood in more detail from the following description taken in conjunction with the accompanying drawings, in which:

FIG. 1 depicts a schematic view of an apparatus adequate for performing a method of packaging semiconductor devices in accordance with some exemplary embodiments;

FIG. 2 depicts a schematic view of a flexible substrate of FIG. 1 in accordance with some exemplary embodiments;

FIG. 3 depicts a schematic view of a first packaging module of FIG. 1 in accordance with some exemplary embodiments;

FIGS. 4 to 6 depict schematic side views of the screen printing unit of FIG. 1 in accordance with some exemplary embodiments;

FIGS. 7 and 8 depict schematic front views illustrating operations of a second packaging module of FIG. 1 in accordance with some exemplary embodiments;

FIGS. 9 to 13 depict schematic cross-sectional views illustrating the method of packaging the semiconductor devices in accordance with some exemplary embodiments;

FIG. 14 depicts a schematic view of an apparatus adequate for performing a method of packaging semiconductor devices in accordance with some exemplary embodiments; and

FIGS. 15 to 19 depict schematic cross-sectional views illustrating a method of packaging semiconductor devices in accordance with some exemplary embodiments.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when an element or layer is referred to as being ‘on’ another one, it can be directly on the other layer, film, region, or plate, or one or more intervening elements or layers may also be present. On the other hand, it will be understood that when an element is directly disposed on or connected to another element, further another element cannot be present therebetween. Also, though ordinal numbers such as “a first”, “a second”, and “a third” are used to describe various elements, compositions, areas and/or layers in various embodiments of the present invention, these terms are used merely for ease of reference and/or to provide antecedent basis for particular elements, regions, layers, and/or sections. Accordingly, these terms should not be construed to describe or imply a particular sequence or ordering of elements, compositions, areas and/or layers unless explicitly stated.

In the following description, the technical terms are used only for explaining specific exemplary embodiments, and are not intended to limit the present invention. Also, unless otherwise defined, all terms, including technical and scientific terms used herein are understood to have the same meaning as commonly understood by one of ordinary skill in the art to which the invention pertains. It will be further understood that terms, such as those defined in commonly used dictionaries, should be interpreted as having a meaning that is consistent with their meaning in the context of the relevant art. Such terms should not be interpreted in an overly formal sense unless expressly so defined herein.

Some example embodiments are described herein with reference to schematic illustrations of particular example embodiments. Variations from the sizes and shapes of the illustrations, as a result, for example, of manufacturing techniques and/or tolerances, are to be expected. Furthermore, these schematics are not drawn to scale. Thus, example embodiments should not be construed as limited to the particular sizes or shapes of regions illustrated herein. For example, deviations in the illustrated shapes resulting from, for example, the use of a particular production method and/or design tolerances of the process or attendant components are to be expected. As such, it should be appreciated that the regions illustrated in the figures are not intended to illustrate the actual size or shape of a region of a device, apparatus, region, or zone, and are not intended to limit the scope of the present inventive concept or claims.

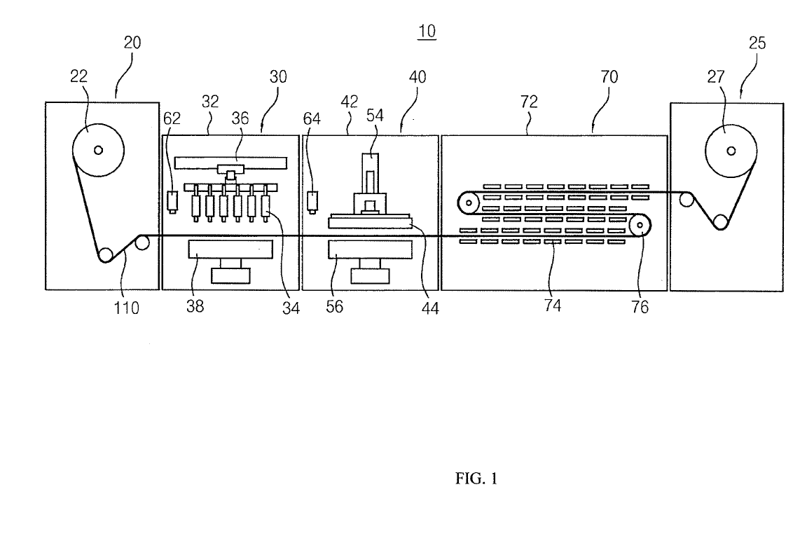

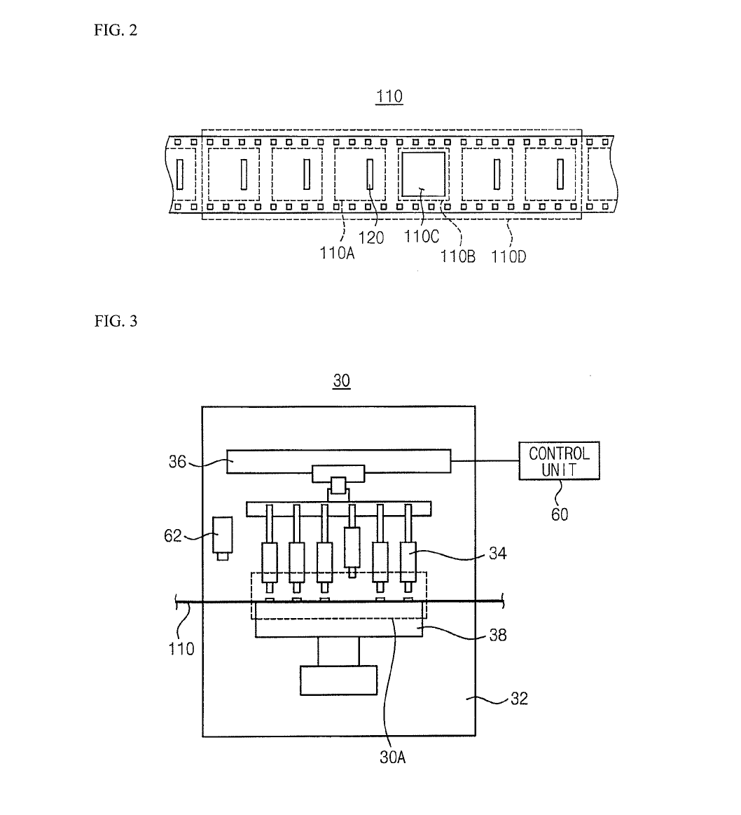

FIG. 1 depicts a schematic view of an apparatus for performing a method for packaging semiconductor devices in accordance with some exemplary embodiments, and FIG. 2 depicts a schematic view of a flexible substrate as depicted in FIG. 1.

Referring to FIGS. 1 and 2, an apparatus 10 for packaging semiconductor devices 120 may be used to package the semiconductor devices 120 mounted on a flexible substrate 110. In particular, the flexible substrate 110 may be a chip on film (COF) type tape for manufacturing a COF type semiconductor package. Additionally or alternatively, the flexible substrate 110 may be implemented as a TCP tape, a ball grid array (BGA) tape or an application specific integrated circuit (ASIC) tape.

The flexible substrate 110 may have a longitudinally extending tape shape and, as illustrated in FIG. 2, the flexible substrate 110 may include a plurality of packaging areas 11 OA extending along the length thereof. The semiconductor devices 120 may be mounted on the packaging areas 11 OA by, for example, a die bonding process.

After performing the die bonding process, the semiconductor devices 120 mounted on the flexible substrate may be inspected via an inspection process. The inspection process may identify defective semiconductor devices among the semiconductor devices 120. These defective semiconductor devices may be removed from the flexible substrate 110. For example, the defective semiconductor devices 120 may be removed from the flexible substrate 110 by a “punching” process. As a result, the flexible substrate 110 may include one or more empty areas 110B on which the semiconductor device 120 is not mounted due to the removal of the defective semiconductor devices during the inspection process, as illustrated in FIG. 2. As a result of the “punching” process, a punch hole 110C may be formed in the empty area 110B.

In accordance with some exemplary embodiments, a plurality of packaging groups 110D may be defined on the flexible substrate 110. Each of packaging groups 110D may include a predetermined number of packaging areas 110A. For example, each of the packaging groups 110D may include six packaging areas 110A. However, it should be appreciated that the number of packaging areas 110A defined within the packaging groups 110D may vary. For example, a given packaging group may include more than six or fewer than six packaging areas 110A. In some embodiments, different packaging groups may include different numbers of packaging areas.

Referring again to FIG. 1, the packaging apparatus 10 may include an unwinder module 200 for supplying the flexible substrate 110 and a rewinder module 25 for recovering the flexible substrate 110. The unwinder module 20 and the rewinder module 25 may include a supply reel 22 for supplying the flexible substrate 110 and a recovery reel 27 for recovering the flexible substrate 110, respectively. Furthermore, although not shown, each of the unwinder module 20 and the rewinder module 25 may include a driving unit for rotating each of the supply reel 22 and the recovery reel 27, respectively.

A first packaging module 30 and a second packaging module 40 may be disposed between the unwinder module 20 and the rewinder module 25. The first packaging module 30 and the second packaging module 40 may perform a packaging process on the semiconductor devices 120.

FIG. 3 depicts a schematic view of a first packaging module of FIG. 1. The first packaging module 30 may include a first packaging chamber 32. The flexible substrate 110 may be transferred lengthwise through the first packaging chamber 32.

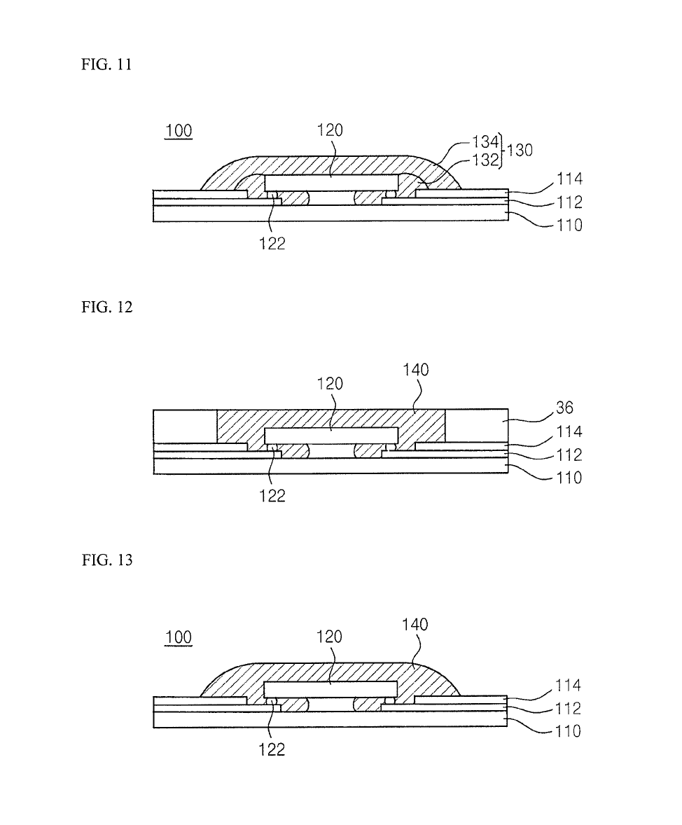

In accordance with some exemplary embodiments, a heat dissipation paint composition may be applied on the semiconductor devices 120 located in the packaging chamber 32. First heat dissipation layers (see, e.g., reference numeral 130 of FIG. 11) for packaging the semiconductor devices 120 may be formed on the semiconductor devices 120. In the present example embodiment, the first heat dissipation layers 130 may be formed by a potting process. For example, potting units 34 for applying the heat dissipation paint composition on the semiconductor devices 120 may be disposed in the packing chamber 32. For example, six potting units 34 corresponding to the packaging areas 110A may be disposed in the first packaging chamber 32. The packaging areas 110A may constitute a single packaging group 110D.

The potting units 34 may be movable along vertical and horizontal axes by a first packaging driving unit 36. For example, although not shown in detail, the first packaging driving unit 36 may include a Cartesian coordinate robot that is configured to move the potting units 34 along vertical and horizontal axes.

The packaging chamber 32 may also house a support member 38 for supporting the flexible substrate 110. The support member 38 may have a flat top surface. As illustrated in the drawings, the support member 38 may partially support the flexible substrate 110 disposed under the potting units 34. In some embodiments, the support member 38 may have a plurality of vacuum holes (not shown) to adsorb and fix portions of the flexible substrate 110 to the support member 38 by using a vacuum. Also, although not shown in detail, the support member 38 may move in a vertical direction to support the flexible substrate 110.

As illustrated in FIG. 3, a first processing region 30A may be defined in the packaging chamber 32. The first processing region 30A may define the area in which the potting process for forming the first heat dissipation layers 130 is performed. The first process region 30A may be defined between the potting units 34 and the support member 38. The potting units 34 may perform the first packaging process with respect to the semiconductor devices disposed in the first processing region 30A, i.e., the packaging group 110D disposed in the first processing region 30A.

If there is an empty area 110B among the packaging regions 110A located in the first processing region 30A. The packaging process may be performed on the semiconductor devices 120 corresponding to each of the packaging areas 110A other than the empty area 110B. The packaging process may be performed simultaneously on the packaging areas 110A.

As illustrated in FIG. 3, the first packaging driving unit 36 may cause each of the potting units 34 to descend so that the potting units 34 are adjacent to the semiconductor devices 120. However, the first packaging driving unit 32 may also be configured to prevent any potting units disposed over empty areas, such as the empty area 110B, from descending. Also, the first packaging driving unit 36 may be configured to horizontally move the potting units 34 so that the first packaging process on the semiconductor devices 120 is performed simultaneously. The heat dissipation paint composition may be applied on the semiconductor devices 120 by the remaining potting units 34. Thus, the semiconductor devices 120 may be packaged by the heat dissipation paint composition.

In accordance with some exemplary embodiments, the packaging apparatus 10 may include a camera 62 for detecting the empty area 110B, and a control unit 60 for controlling operations of the first packaging driving unit 36 and the potting units 34. The control unit may control the first packaging driving unit 36 and the potting units 34 so that the first packaging process is not performed on the empty area 110B. The camera 62 may be located in the first packaging chamber 32 and may be configured to inspect whether an empty area 110C is included in the packaging group 110D located in the first processing region 30A.

Additionally or alternatively, information indicating that an empty area 110B is present may be obtained and provided to the control unit 60 prior to the packaging process. That is, data generated from the inspection process and punching process with respect to the semiconductor devices 120 may be provided into the control unit 60 to configure or otherwise assist with the packaging process. The control unit 60 may control the operations of the first packaging driving unit 36 and the potting units 34 by using the previously provided data and data detected by the camera 62.

In accordance with some exemplary embodiments, if an empty area 110B is not detected from among the packaging areas 110A, the first packaging process may be omitted, and the packaging areas 110A may be transferred into the second packaging module.

Referring again to FIG. 1, the second packaging module 40 may include a second packaging chamber 42. The flexible substrate 110 may be horizontally transferred through the second packaging chamber 42.

In accordance with an exemplary embodiment, heat dissipation paint composition may be applied on semiconductor devices 120 located in the second packaging chamber 42. Thus, second heat dissipation layers (see reference numeral 140 of FIG. 13) for packaging the semiconductor devices 120 may be formed on the semiconductor devices 120. The second heat dissipation layers 140 may be formed at the same time by a screen printing process. For example, a screen potting unit 44 for applying the heat dissipation paint composition on the semiconductor devices 120 may be disposed in the second packing chamber 42.

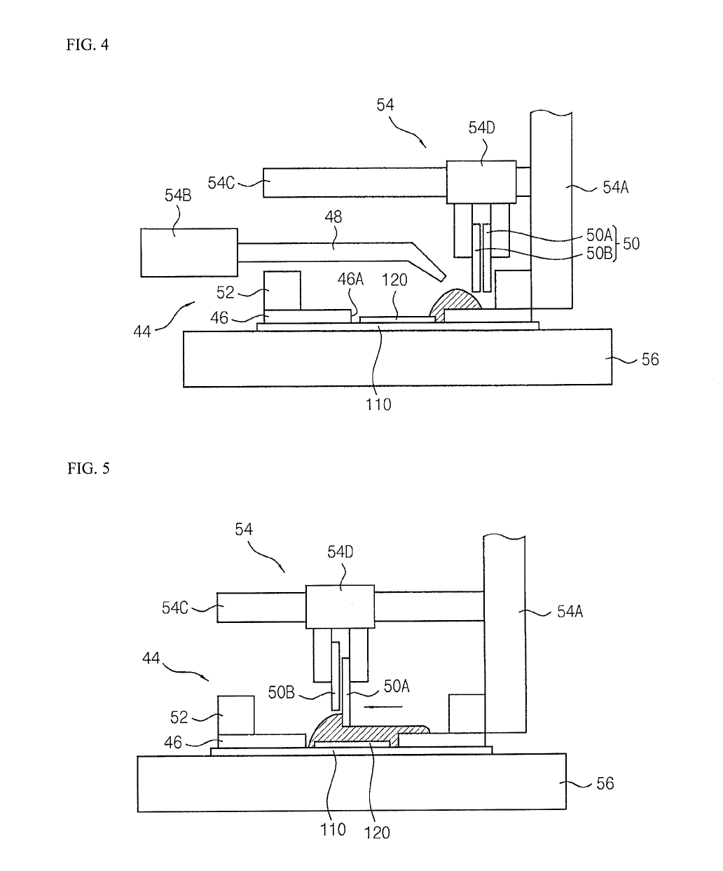

FIGS. 4 to 6 are schematic side views of the screen printing unit of FIG. 1. Referring to FIGS. 4 to 6, the screen printing unit 44 may include a mask 46, a nozzle 48, and a squeegee 50. The mask may define openings 46A through which the heat dissipation paint composition is applied on the semiconductor devices 120. The nozzle 48 may supply the heat dissipation paint composition on the mask 46. The squeegee 50 may fill the openings 46A with the heat dissipation paint composition.

The second packaging module 40 may include a second packaging driving unit 54 for vertically moving the screen printing unit 44 to place the mask 46 onto the flexible substrate 110 and horizontally moving the squeegee 50 to fill the opening 46A with the heat dissipation paint composition.

According to some exemplary embodiments, the mask 46 may define a plurality of openings 46A corresponding to the semiconductor devices 120 included in one packaging group 110D. For example, the mask 46 may have six openings 46A. The mask 46 may be mounted on a bottom surface of a frame 52 having a square ring shape. The frame 52 may have a predetermined thickness (e.g., 1 mm, 3 mm, 5 mm, or 1 cm) to prevent the heat dissipation paint composition supplied on the mask 46 from leaking beyond the mask. The frame 42 may be connected to the second packaging driving unit 54.

Each of the openings 46A may expose the semiconductor device 120 and a portion of a top surface of the flexible substrate 110 that is adjacent to the semiconductor device 120.

The second packaging driving unit 54 may include a first driving unit 54A for vertically moving the screen printing unit 44, a nozzle driving unit 54B for moving the nozzle 48, a horizontal driving unit 54C for horizontally moving the squeegee 50, and a second vertical driving unit 54D for vertically moving the squeegee 50.

The first driving unit 54A may be connected to the frame 52 to allow the screen printing unit 44 to descend so that the mask 46 is brought into close contact with the flexible substrate 110. The nozzle driving unit 54B may move the nozzle 48 so that the heat dissipation paint composition is supplied to a predetermined position on the mask 46. The nozzle driving unit 54B may move the nozzle 48 so that the squeegee 50 and the nozzle 48 do not interfere with each other.

In accordance with some exemplary embodiments, the screen printing unit 44 may include a first squeegee 50A and second squeegee 50B for filling the openings 46A with heat dissipation paint composition.

The first squeegee 50A may be spaced a predetermined distance upward from the mask 46 as illustrated in FIG. 5. The first squeegee may be moved in a first horizontal direction by the horizontal driving unit 54C. The horizontal movement of the first squeegee may cause the heat dissipation paint composition to be filled into the openings 46A. As a result, the second heat dissipation layers 140 for packaging the semiconductor devices 120 may be formed in the openings 46A.

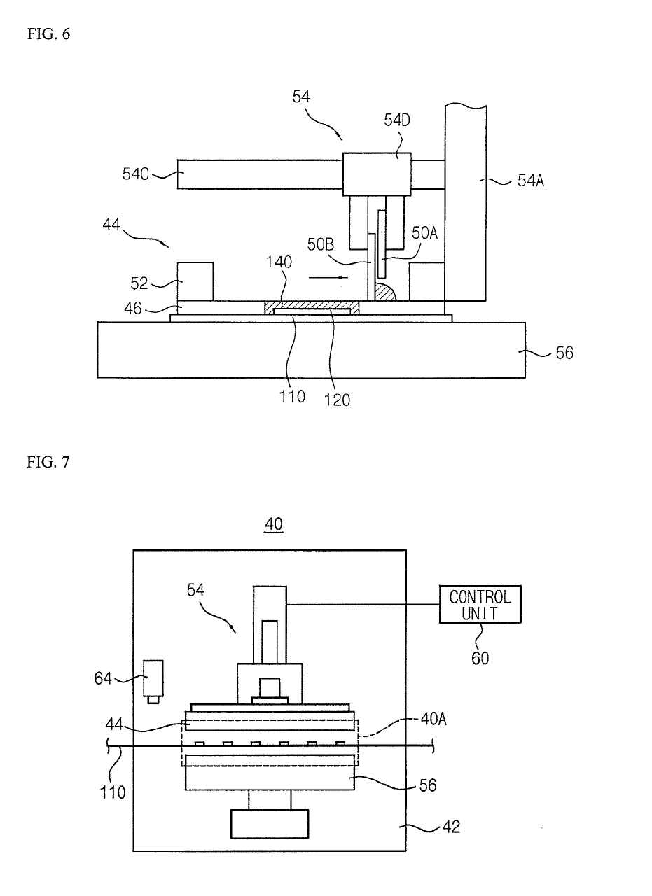

The second squeegee 50B may be moved in a second horizontal direction opposite to the first horizontal direction to remove the surplus heat dissipation paint composition remaining on the mask 46, as illustrated in FIG. 6. Here, the second squeegee 50B may be brought into close contact with a top surface of the mask 46 by the second vertical driving unit 54D.

In accordance with some exemplary embodiments the screen printing process may be performed by using a single squeegee. In this case, the second vertical driving unit 54D may adjust a height of the squeegee. For example, when the squeegee is moved in the first horizontal direction, the squeegee may be spaced a predetermined distance from the top surface of the mask 46. When the squeegee is moved in the second horizontal direction, the squeegee may be brought into close contact with the top surface of the mask 46.

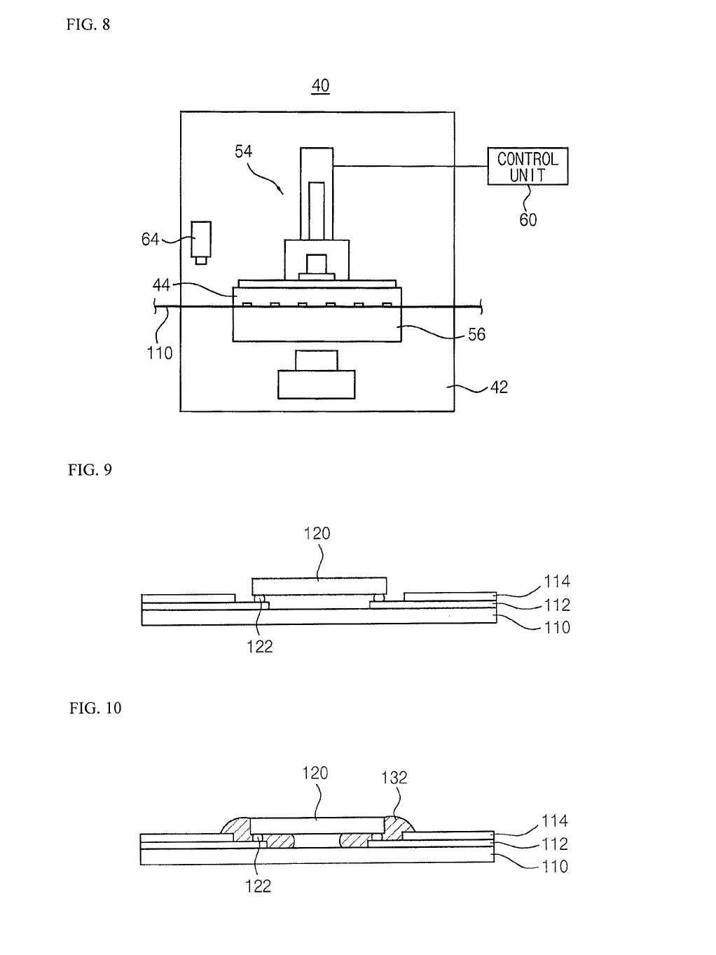

FIGS. 7 and 8 depict schematic front views illustrating operations of the second packaging module of FIG. 1. Referring to FIG. 7, a support member 56 for supporting the flexible substrate 110 may be disposed in the second packaging chamber 42. The support member 56 may have a flat top surface. As illustrated in the drawings, the support member 56 may partially support the flexible substrate 110 disposed under the screen printing unit 44. The support member 56 may have a plurality of vacuum holes (not shown) to adsorb and fix portions of the flexible substrate 110 disposed on the support member 56 to the support member 56 by using a vacuum. Also, although not shown in detail, the support member 56 may be vertically movable to support the flexible substrate 110.

As illustrated in FIG. 7, a second processing region 40A in which the second packaging process is performed may be defined in the second packaging chamber 42. The second processing region 40A may be defined between the screen printing units 44 and the support member 56. Thus, the screen printing unit 44 may perform the second packaging process with respect to the semiconductor devices 120 disposed in the second processing region 40A. For example, one packaging group 110D may be disposed in the second processing region 40A. The second packaging process may be performed simultaneously with respect to each of the semiconductor devices 120 within a particular packaging group 110D. For example, the packaging process may be performed on each of the six semiconductor devices 120 of the packaging group 110D.

Operations of the second packaging module 40 may be controlled by the control unit 60. The second packaging chamber may also include a camera 64 configured to inspect the packaging group 110D transferred into the second processing region 40A.

In accordance with some exemplary embodiments, the first packaging process and the second packaging process may be selectively performed with respect to the packaging groups 110D. For example, the first packaging process and the second packaging process may be selected according to whether an empty area 110B is located in the packaging group 110D.

For example, when a first packaging group includes the empty area 110B, and a second packaging group does not include the empty area 110B, the first packaging process may be performed with respect to the first packaging group, and the second packaging process may be performed with respect to the second packaging group.

If the second packaging process is performed with respect to the first packaging group, the heat dissipation paint composition supplied onto the mask 46 may be supplied into the punch hole 110C of the empty area 110B. Thus, it is desirable that the first packaging process is performed with respect to the first packaging group, and the second packaging process is performed with respect to the second packaging group.

Since the time required for the second packaging process, i.e., the screen printing process, is less than that required for the first packaging process, i.e., the potting process, it is desirable that the second packaging process is performed with respect to the second packaging group that does not include the empty area 110B.

Referring again to FIG. 1, the packaging apparatus 10 may include a curing module 70 for curing the first or second heat dissipation layers 130 or 140 formed on the semiconductor devices 120. The curing module 70 may include a curing chamber 72. The flexible substrate 110 may be transferred through the curing chamber 72. A plurality of heaters 74 may be disposed along a transfer path of the flexible substrate 110 within in the curing chamber 72. The curing chamber 62 may also include rollers 76 for adjusting a transfer distance of the flexible substrate 110. For example, the flexible substrate 110 may be transferred along a transfer path having a serpentine pattern. The first or second heat dissipation layers 130 or 140 may be cured by the heaters 74.

Hereinafter, a method of packaging the semiconductor devices 120 in accordance with an exemplary embodiment will be described with reference to the accompanying drawings. FIGS. 9 to 13 depict schematic cross-sectional views illustrating the method of packaging the semiconductor devices in accordance with an exemplary embodiment.

As illustrated in FIG. 1, the flexible substrate 110 may be transferred between the unwinder module 20 and the rewinder module 25 through the first packaging module 30, the second packaging module 40, and the curing module 70.

As illustrated in FIG. 9, signal lines 112 such as conductive patterns may be disposed on the flexible substrate 110. Also, an insulation layer 114 for protecting the signal lines 112 may be disposed on the flexible substrate 110. The semiconductor devices 120 may be bonded to the flexible substrate 110 so that the semiconductor devices 120 are connected to the signal lines 112 through gold bumps and/or solder bumps 122. For example, each of the signal lines 112 may be formed of a conductive material such as copper. The insulation layer 114 may be a surface resist (SR) layer or a solder resist layer.

For example, when a first packaging group including the empty area 110B is transferred into the first packaging module 30, the empty area 110B may be detected by the camera 62. After the first packaging group is located in the first processing region 30A, first heat dissipation layers 130 may be formed on the semiconductor devices 120 of the first packaging group. Here, the control unit 60 may control the operations of the first packing module 30 so that the first packaging process is omitted on the empty region 110B.

The heat dissipation paint composition may be applied on the semiconductor devices 120 by the potting units 34 in the first processing region 30A. Thus, the first heat dissipation layers 130 may be formed on the semiconductor devices 120.

In accordance with some exemplary embodiments, as illustrated in FIG. 10, the heat dissipation paint composition may be applied onto side surfaces of the semiconductor device 120 and portions of top surface of the flexible substrate 110 adjacent to the side surfaces of the semiconductor device 120 to form a lateral heat dissipation layer 132. Then, as illustrated in FIG. 11, the heat dissipation paint composition may be applied to the top surface of the semiconductor device 120 to form an upper heat dissipation layer 134.

The first packaging driving unit 36 may allow the potting units 34 to descend so that the potting units 34 are disposed adjacent to the semiconductor devices 120 on the remaining packaging areas 110A, aside from the empty area 110B. Then, to form the lateral heat dissipation layer 132, the potting units 34 may horizontally move along the side surfaces of the semiconductor devices 120. The potting units 34 may horizontally move across the semiconductor devices 120 to form the upper heat dissipation layer 134.

As another example, when a second packaging group that does not include an empty area 110B is transferred into the first packaging module 30, the control unit 60 may control operations of the unwinder module 20 and the rewinder module 25 so that the second packaging group first passes through the first packaging module 30 and then into the second packaging module 40.

Referring to FIG. 12, the second packaging process, i.e., the screen printing process, may be performed with respect to the semiconductor devices 120 of the second packaging group that is transferred into the second processing region 40A of the second packaging module 40. For example, the mask 46 defining the openings 46A may be disposed on the flexible substrate 110, and the heat dissipation paint composition may be supplied onto the mask 46 through the nozzle 48. Then, the inside of each of the openings 46A may be filled with the heat dissipation paint composition by using the squeegee 50.

After the screen printing process is performed, the mask 46 may be removed from the flexible substrate 110. Thus, as illustrated in FIG. 13, the second heat dissipation layers for packaging the semiconductor devices 120 may be formed on the flexible substrate 110.

While the first or second packaging process is performed, the heat dissipation paint composition may infiltrate into spaces between the flexible substrate 110 and the semiconductor devices 120. However, if the heat dissipation paint composition does not sufficiently infiltrate into the spaces between the flexible substrate 110 and the semiconductor devices 120, air layers may be formed between the flexible substrate 110 and the semiconductor devices 120 as illustrated in the drawings.

In accordance with some exemplary embodiments, the viscosity of the heat dissipation paint may be adjusted to ensure that the heat dissipation paint composition sufficiently infiltrates into the spaces between the flexible substrate 110 and the semiconductor devices 120. In such cases, one or more underfill layers may be formed between the flexible substrate 110 and the semiconductor devices 120 by the infiltration of the heat dissipation paint composition.

After the first or second heat dissipation layers 130 or 140 are formed, the flexible substrate 110 may be transferred into the curing chamber 72. When the flexible substrate 110 is transferred through the curing chamber 72, the first or second heat dissipation layers 130 or 140 on the semiconductor devices 120 may be cured. The first or second heat dissipation layers 130 or 140 may be curable at a temperature of about 140° C. to about 160° C. For example, the heat dissipation layers 130 may be cured at a temperature of about 150° C. Curing the heat dissipation layers 130 may complete the packaging process, thus providing semiconductor packages 100 having improved heat dissipation characteristics and flexibility.

In accordance with some example embodiments, the heat dissipation paint composition may include an epichlorohydrin bisphenol A resin, a modified epoxy resin, a curing agent, a curing accelerator, a heat dissipation filler, and/or combinations thereof. In particular, in some exemplary embodiments the heat dissipation paint composition may include approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator and the remaining amount of the heat dissipation filler.

The use of epichlorohydrin bisphenol A resin may improve the adhesiveness of the heat dissipation paint composition, and the use of modified epoxy resin may improve the flexibility and the elasticity of the heat dissipation layer during and after the curing process. Particularly, the modified epoxy resin may include a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, an acrylic rubber modified epoxy resin (ARMER), an urethane modified epoxy resin, a silicon modified epoxy resin, and the like.

The curing agent may include a novolac type phenolic resin. For example, a novolac type phenolic resin obtained by reacting one of phenol, cresol and bisphenol A with formaldehyde may be used.

The curing accelerator may include an imidazole-based curing accelerator or an amine-based curing accelerator. For example, the imidazole-based curing accelerator may include imidazole, isoimidazole, 2-methylimidazole, 2-ethyl-4-methylimidazole, 2,4-dimethylimidazole, butylimidazole, 2-methylimidazole, 2-phenylimidazole, 1-benzyl-2-methylimidazole, 1-propyl-2-methylimidazole, 1-cyanoethyl-2-methylimidazole, 1-cyanoethyl-2-ethyl-4-methylimidazole, phenylimidazole, benzylimidazole, and the like, and combinations thereof.

The amine-based curing accelerator may include an aliphatic amine, a modified aliphatic amine, an aromatic amine, a secondary amine, a tertiary amine, and the like, and combinations thereof. For example, the amine-based curing accelerator may include benzyldimethylamine, triethanolamine, triethylenetetramine, diethylenetriamine, triethylamine, dimethylaminoethanol, m-xylenediamine, isophorone diamine, and the like, and combinations thereof.

The heat dissipation filler may include aluminum oxide having a particle size of approximately 0.01 μm to approximately 50 μm, and preferably, of approximately 0.01 μm to approximately 20 μm. The heat dissipation filler may be used to improve the thermal conductivity of the cured heat dissipation layer 130. Particularly, the heat dissipation paint composition may include approximately 75 wt % to approximately 95 wt % of the heat dissipation filler based on the total amount of the heat dissipation paint composition. The thermal conductivity of the heat dissipation layer 130 may be adjusted to be within a range of approximately 2.0 W/mK to approximately 3.0 W/mK. In addition, the adhesiveness of the heat dissipation layer 130 may be adjusted to be within a range of approximately 8 MPa and approximately 12 MPa by the epichlorohydrin bisphenol A resin and the modified epoxy resin.

The viscosity of the heat dissipation paint composition may be adjusted to be within a range of approximately 100 Pas to approximately 200 Pas, and the heat dissipation paint composition may be cured in a temperature range of approximately 140° C. to approximately 160° C. The viscosity of the heat dissipation paint composition may be measured by using a B type rotational viscometer and may be particularly measured at a rotor rotation velocity of approximately 20 rpm at a temperature of approximately 23° C.

In accordance with some exemplary embodiments, the heat dissipation layer 130 may be formed directly on the top surface and the side surfaces of the semiconductor device 120, thereby improving and the heat dissipation efficiency from the semiconductor device 120. Since the heat dissipation layer 130 has improved flexibility and adhesiveness, the likelihood of separation of the heat dissipation layer 130 from the flexible substrate 110 and the semiconductor device 120 may be reduced. Also, the flexibility of the semiconductor package 100 may be largely improved when compared to conventional packaging and heat dissipation techniques.

The productivity of the semiconductor packaging process may be improved through the use of packaging groups, such as the packaging group 110D. These packaging groups, comprising a plurality of packaging areas 110A, may advantageously provide for selection of either a first packaging process or a second packaging process based on whether an empty area is defined within the packaging group. The selective use of packaging processes in this manner may provide significantly increased productivity in the packaging process by allowing more efficient processes to be used in the event a group contains no empty spaces.

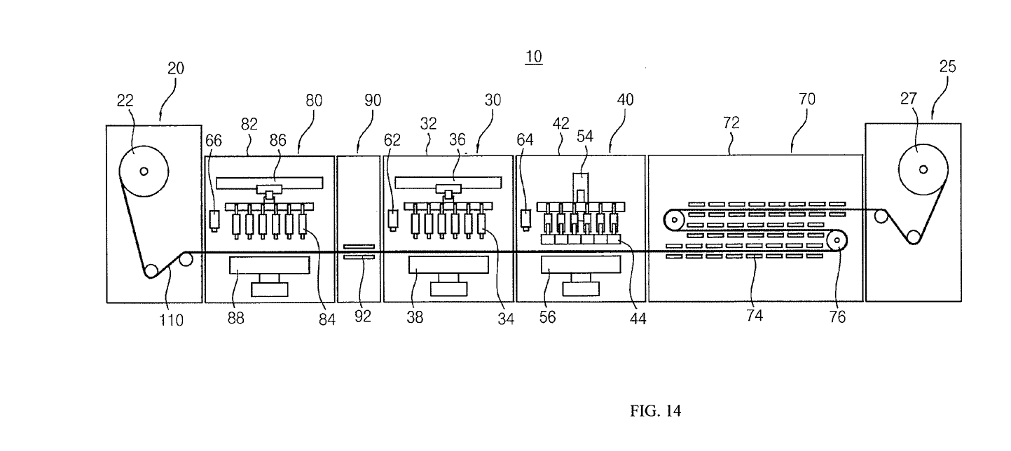

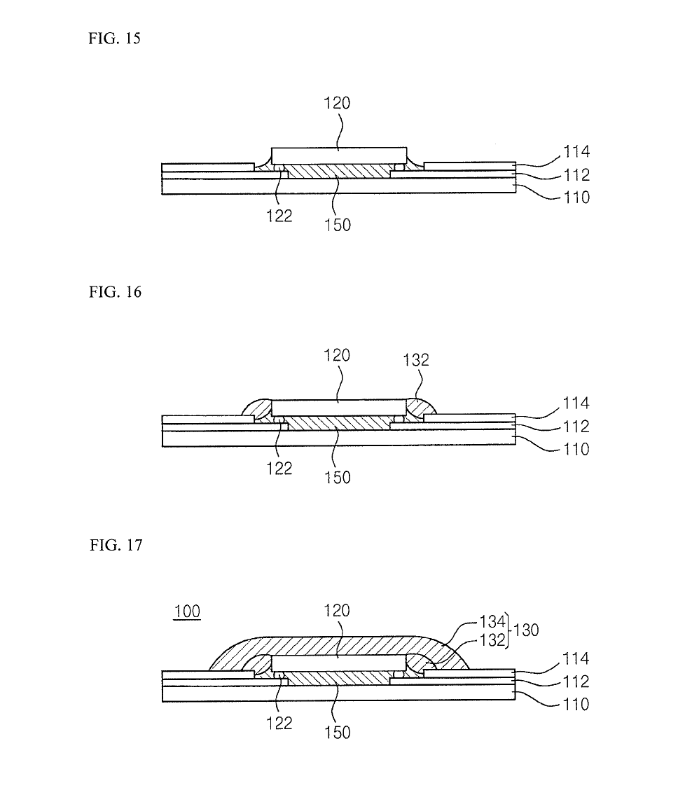

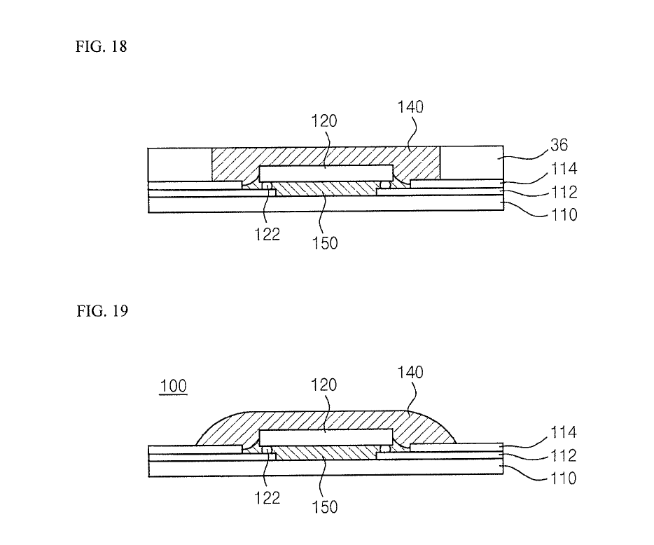

FIG. 14 depicts a schematic view of an apparatus for performing a method of packaging semiconductor devices in accordance with some exemplary embodiments, and FIGS. 15 to 19 depict schematic cross-sectional views illustrating a method of packaging semiconductor devices in accordance with some exemplary embodiments.

Referring to FIG. 14, an apparatus 10 for packaging semiconductor devices 120 may include an underfill module 70 for forming underfill layers (see, e.g., reference numeral 150 of FIG. 15) between a flexible substrate 110 and the semiconductor devices 120 and a pre-curing module 80 for curing the underfill layers 150. The underfill module 80 and the pre-curing module 90 may be disposed between an unwinder module 20 and a first packaging module 30. The flexible substrate 110 may be transferred into the first packaging module 30 through the underfill module 80 and the pre-curing module 90.

The underfill module 80 may include an underfill chamber 82. The flexible substrate 110 may be horizontally transferred through the underfill chamber 82. The underfill module 80 may also include potting units 84 for injecting an underfill resin between the flexible substrate 110 and the semiconductor devices 120 disposed in the underfill chamber 82. The potting units 84 may be movable in vertical and horizontal directions by an underfill driving unit 86.

Further, a support member 88 may be provided for supporting the flexible substrate 110 within the underfill chamber 82. Although not shown, the support member 88 may define vacuum holes for adsorbing and fixing the flexible substrate 110 to the support member 88. Also, a third processing region (not shown) in which an underfill process is performed may be defined in the underfill chamber 82. The third processing region may be defined between the potting units 84 and the support member 88. The underfill process may be performed simultaneously with respect to the semiconductor devices 120 disposed in the third processing region.

The underfill module 80 may include a plurality of potting units 84 corresponding to the packaging areas 110A included in one packaging group 110D. For example, the underfill module 80 may include six potting units 84. The underfill module 80 may also include a camera 66 for detecting an empty region 110B from among the packaging regions 119A of the flexible substrate 110 within the underfill chamber 82. Operations of the underfill driving unit 86 and the potting units 84 may be controlled by a control unit 60. In particular, the control unit may control the underfill driving unit 76 and the potting units 84 so that the underfill process is omitted on the empty region 110B.

When an empty region 110B is included in the packaging group 110D and transferred into the underfill module 80, the underfill driving unit 86 may allow the remaining potting units 84 to descend so that the potting units are adjacent to the semiconductor devices. One or more potting units associated with the empty region 110B may be prevented from descending. Also, the underfill driving unit 86 may horizontally move the potting units 84 so that the underfill process is performed simultaneously with respect to each of the semiconductor devices 120. The potting unit 84 disposed over the empty region 110B may not operate, in order to prevent the underfill resin from being supplied into a punch hole 110C of the empty region 110B.

After the underfill process is performed by the underfill module 80, the flexible substrate 110 may be transferred into the first packaging module 30 through the pre-curing module 90. The pre-curing module 90 may include a heater 92 for curing the underfill layers 150.

Referring to FIG. 15, the potting units 84 may supply the underfill resin to a portion of the top surface of the flexible substrate 110 that is adjacent to side surfaces of the semiconductor devices 120. The underfill resin may infiltrate into spaces between the flexible substrate 110 and the semiconductor devices 120 by surface tension. As described above, the underfill layers 150 formed between the flexible substrate 110 and the semiconductor devices 120 may be cured at a temperature of about 150° C. while passing through the pre-curing module 90.

The underfill resin may include an epoxy resin, a curing agent, a curing accelerator, an inorganic filler, and combinations thereof. The epoxy resin may include a bisphenol A type epoxy resin, a bisphenol F type epoxy resin, a bisphenol S type epoxy resin, a naphthalene type epoxy resin, a phenol novolac type epoxy resin, a cresol novolac epoxy resin, and the like, and combinations thereof. An amine-based curing agent and an imidazole-based curing accelerator may be used as the curing agent and the curing accelerator, respectively.

Aluminum oxide may be used as the inorganic filler to improve the thermal conductivity of the underfill layer 140. The aluminum oxide may have a particle size in a range between approximately 0.01 μm and approximately 20 μm.

Referring to FIGS. 16 and 19, after the underfill layers 150 are formed, first or second heat dissipation layers 130 or 140 may be formed on the semiconductor devices 120 and the flexible substrate 110. Since an example of a method of forming the first or second heat dissipation layers 130 or 140 is substantially similar to that previously described above with reference to FIGS. 9 to 13, detailed redundant description of this exemplary method will be omitted.

Alternatively, the underfill process using the underfill resin may be performed after a die bonding process in which the semiconductor devices 120 are mounted on the flexible substrate 110. In this case, the semiconductors 120 may be packaged by using the packaging apparatus and method, which were previously described above with reference to FIGS. 1 to 13.

In accordance with exemplary embodiments, the first or second heat dissipation layers 130 or 140 may be formed on the flexible substrate 110 and the semiconductor devices 120, and the semiconductor devices 120 may be packaged by the first or second heat dissipation layers 130 or 140.

In particular, since the packaging groups 111D are defined, and the first or second packaging process is selectively performed according to whether the empty area 110B exists in each of the packaging groups 110D, productivity of the packaging process for the semiconductor packages 100 may be significantly improved.

The heat dissipation layer 130 may improve in flexibility and adhesion due to the epichlorohydrin bisphenol A resin and the modified epoxy resin, and may have relatively higher thermal conductivity due to the heat dissipation filler. Accordingly, the heat dissipation efficiency from the semiconductor device 120 may be greatly improved by the heat dissipation layer 130. Particularly, since the heat dissipation layer 130 has improved flexibility and adhesion, the likelihood of a separation of the heat dissipation layer 130 from the flexible substrate 110 and the semiconductor 120 may be reduced while maintaining the flexibility of the flexible substrate 110.

Additionally, the underfill layer 140 may be formed with an improved thermal conductivity between the flexible substrate 110 and the semiconductor device 120, thereby more increasing the efficiency of heat dissipation from the semiconductor device 120.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of packaging semiconductor devices mounted on a flexible substrate having a longitudinally extending tape and comprising packaging areas arranged along an extending direction thereof, the method comprising:
determining whether an empty area in which a semiconductor device is not mounted is present among the packaging areas;
in response to determining that the empty area is present, applying a heat dissipation paint composition on the semiconductor devices mounted on the packaging areas other than the empty area to form first heat dissipation layers; and
in response to determining that the empty area is not present, applying the heat dissipation paint composition on the semiconductor devices mounted on the packaging areas to form second heat dissipation layers
wherein the first heat dissipation layers are formed by a potting process, and the second heat dissipation layers is formed by a screen printing process.

2. The method of claim 1, wherein the flexible substrate is transferred through a first packaging module for performing the potting process and a second packaging module for performing the screen printing process.

3. The method of claim 2, wherein, in response to determining that the empty area is present, the potting process is performed simultaneously on the remaining packaging areas, other than the empty area, located in a processing region of the first packaging module.

4. The method of claim 2, wherein, in response to determining that the empty area is not present among the packaging areas, transferring the packaging areas located in the processing region of the first packaging module into the second packaging module.

5. The method of claim 2, wherein the screen printing process is performed simultaneously on the packaging areas located in a processing region of the second packaging module.

6. The method of claim 1, further comprising curing the first or second heat dissipation layers.

7. The method of claim 6, wherein the flexible substrate is transferred through a curing module, and the first or second heat dissipation layers are cured by heaters disposed in the curing module.

8. The method of claim 1, further comprising forming underfill layers filling at least one space defined between the flexible substrate and the semiconductor devices.

9. The method of claim 8, wherein the forming of the underfill layers comprises:
transferring the flexible substrate through an underfill module; and
forming the underfill layers between the packaging areas of the flexible substrate and the semiconductor devices located in a processing region of the underfill module, wherein an underfill process is omitted on the empty area.

10. The method of claim 8, further comprising curing the underfill layers.

11. The method of claim 1, wherein the heat dissipation paint composition comprises approximately 1 wt % to approximately 5 wt % of an epichlorohydrin bisphenol A resin, approximately 1 wt % to approximately 5 wt % of a modified epoxy resin, approximately 1 wt % to approximately 10 wt % of a curing agent, approximately 1 wt % to approximately 5 wt % of a curing accelerator and the remaining amount of a heat dissipation filler.

12. The method of claim 11, wherein the modified epoxy resin is a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin or a silicon modified epoxy resin.

13. The method of claim 11, wherein the curing agent is a novolac type phenolic resin.

14. The method of claim 11, wherein the curing accelerator is an imidazole-based curing accelerator or an amine-based curing accelerator.

15. The method of claim 11, wherein the heat dissipation filler comprises aluminum oxide having a particle size of approximately 0.01 μm to approximately 50 μm.

16. A method of packaging semiconductor devices mounted on a flexible substrate having a longitudinally extending tape shape, comprising packaging areas arranged along an extending direction thereof, and on which a plurality of packaging groups constituted by the predetermined number of packaging areas are defined, the method comprising:
transferring the flexible substrate through a first packaging module in which a potting process is performed to form first heat dissipation layers on the semiconductor devices and a second packaging module in which a screen printing process is performed to form second heat dissipation layers on the semiconductor devices;
determining whether an empty area in which a semiconductor device is not mounted is present among the packaging areas;
in response to determining that the empty area is present, applying a heat dissipation paint composition on the semiconductor devices mounted on the remaining packaging areas except for the empty area, to form the first heat dissipation layers; and
in response to determining that the empty area is not present, applying the heat dissipation paint composition on the semiconductor devices mounted on the packaging areas of a packaging group to form the second heat dissipation layers.

17. An apparatus for packaging semiconductor devices mounted on a flexible substrate having a longitudinally extending tape shape and comprising packaging areas arranged along an extending direction thereof, the apparatus comprising:
an unwinder module configured to supply the flexible substrate;
a rewinder module configured to recover the flexible substrate;
a first packaging module disposed between the unwinder module and the rewinder module to apply a heat dissipation paint composition on the semiconductor devices by using a potting process, thereby forming first heat dissipation layers configured to package the semiconductor devices;
a second packaging module disposed between the first packaging module and the rewinder module to apply the heat dissipation paint composition on the semiconductor devices by using a screen printing process, thereby forming second heat dissipation layers configured to package the semiconductor devices; and
a control unit configured to detect an empty area on which a semiconductor device is not mounted from among the packaging areas, to control operations of the first packaging module to form the first heat dissipation layers on the semiconductor devices mounted on the remaining packaging areas except for the empty area in response to detecting the empty area, and to control operations of the second packaging module to form the second heat dissipation layers on the semiconductor devices in response to not detecting the empty area.

18. The apparatus of claim 17, further comprising a curing module configured to cure the first or second heat dissipation layers.

19. The apparatus of claim 17, further comprising an underfill module configured to form underfill layers between the flexible substrate and the semiconductor devices.

20. The apparatus of claim 19, further comprising a pre-curing module configured to cure the underfill layers.
